(19) United States
(12) Patent Application Publication
(10) Pub. No.: US 2026/0212103 A1
(43) Pub. Date: Jul. 23, 2026

(54) RISK PREDICTION-AUTOMATION

(71) Applicant: GlobalFoundries Singapore Pte. Ltd., Singapore (SG)

(72) Inventors: Gek Soon Chua, Singapore (SG); Dymasius Yusuf Sitepu, Singapore (SG); Yee Mei Foong, Singapore (SG)

(21) Appl. No.: 19/034,208

(22) Filed: Jan. 22, 2025

(51) Int. Cl. G06F 30/398; G06F 30/392

(52) U.S. Cl. CPC G06F 30/398; G06F 30/392

(57) ABSTRACT

The present disclosure relates to risk prediction automation and, more particularly, to systems and processes of optical proximity correction weak point risk prediction automation in use with semiconductor fabrication processes. The method includes: obtaining, by the computing device, feature variables of a design pattern associated with a design layout; determining, by the computing device, a risk rating value of selected feature variables of the feature variables for the design pattern; and generating, by the computing device, a waiverable disposition score using a machine learning model based on a combination of the risk rating value of the selected feature variables of the design pattern of the design layout.

### BACKGROUND

The present disclosure relates to risk prediction automation and, more particularly, to systems and processes of optical proximity correction weak point risk prediction automation in use with semiconductor fabrication processes.

In advanced semiconductor technology nodes, the model accuracy of optical proximity correction (OPC) is important for integrated circuit (IC) chip mask tape out, yield ramp up, and product time-to-market. An accurate model requires a small prediction error for the full chip layout. As the full chip layout usually has large pattern variety, an optimal pattern with no violations is desired during the model calibration process.

### SUMMARY

In an aspect of the disclosure, a method comprises: obtaining, by the computing device, feature variables of a design pattern associated with a design layout; determining, by the computing device, a risk rating value of selected feature variables of the feature variables for the design pattern; and generating, by the computing device, a waiverable disposition score using a machine learning model based on a combination of the risk rating value of the selected feature variables of the design pattern of the design layout.

In an aspect of the disclosure, a computer program product comprising one or more computer readable storage media having program instructions collectively stored on the one or more computer readable storage media. The program instructions is executable to: obtain feature variables from one or more simulated design layouts; generate violation rules of design patterns of the one or more simulated design layouts; save the feature variables and the violation ratings in a database; and generate a waiverable disposition score using a machine learning model for one or more patterns of a new design layout based on the saved feature variables and the violation ratings.

In an aspect of the disclosure,

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 depicts a cloud computing node according to an embodiment of the present disclosure.

FIG. 2 shows a block diagram of an exemplary processing engine in accordance with aspects of the disclosure.

FIG. 3 shows historical information for determining a waiverable disposition score (WDS) in accordance with aspect of the present disclosure.

FIGS. 4A-4C show illustrative examples in accordance with aspects of the disclosure.

FIG. 5 shows a flowchart of an exemplary method in accordance with aspects of the present disclosure.

### DETAILED DESCRIPTION

The present disclosure relates to risk prediction automation and, more particularly, to systems and processes of optical proximity correction weak point risk prediction automation used with semiconductor fabrication processes. More specifically, the present disclosure provides systems and processes to auto-waive violations in semiconductor fabrication processes by utilizing artificial intelligence. For example, the systems and processes of optical proximity correction weak point risk prediction automation may generate a Waiverable Disposition Score (WDS) obtained from accumulated, historical waived error information to determine whether a layout violation (e.g., OPC or OCR violations) can be pass-waived or failed. For example, the accumulated, historical waived error information may be obtained from a database comprising legacy data, e.g., historical data, of feature variables that were already determined to be pass-waived or failure points of a chip layout.

In more specific embodiments, the systems and processes described herein provide a technical solution to a technical problem related to the challenge of late and unreliable manual disposition of non-conforming violations (e.g., ORC, OPC, etc. violations). For example, the systems and processes described herein, (i) leverage previously waived errors from a comprehensive database, (ii) make large language models that perform classification (e.g., whether a violation in a design layout can be waived) using historical information (e.g., using the waived errors and feature variables of previous design parameters as training data), and (iii) perform auto-disposition and retrieve recommendation via artificial intelligence (e.g., implementing Chatbot technologies with question and answer formats) using the classifications. The auto-disposition can be, for example, providing an indication that a certain violation has a low risk of affecting the functionality of the design.

For example, the systems and processes enhance waiver disposition analysis techniques in response to receipt of various operations covering ORC, OPC, OPC_ORC, OPCV, target, target_no_opc, etc., by leveraging waived errors information from a database comprising previously discovered and saved violations and related feature variables. Using this information, the systems and processes determine a WDS and, in embodiments, augment an alert to include the WDS together with a recommendation. In this way, the systems and processes generate an enriched alert of violations presented to the stakeholders for handling directly, e.g., waiving the violation or, if the violation is above a threshold, stopping production. The systems and processes can provide the violations through a Chatbot format or other graphical user interface.

As should be understood by those of skill in the art, OPC violations occur when adjustments made to a photomask pattern during the OPC process result in a printed feature that does not meet design rules. This may include, for example, having incorrect dimensions, unintended overlaps, or too close spacing between features, often caused by inaccurate modeling of the lithography process or complex layout design elements. The causes of OPC may be, for example, modeling errors, process variations, complex layout features or design rule violations. Common symptoms of OPC violations include, e.g., linewidth variations, corner rounding, line-end shortening or bridging. The OPC violations may be bridged by improved OPC modeling, optimizing layout design to minimize potential OPC issues, adding small auxiliary features to the mask to enhance the printed feature quality or carefully monitoring and adjusting the lithography process parameters.

Moreover, as should be understood by those of skill in the art, ORC violations typically refers to a design flaw detected during an ORC process, where a layout is analyzed to identify potential manufacturing issues related to the limitations of the photolithography process. For example, particularly concerning may be proximity effect, which leads to errors in feature sizes and shapes when very small features are placed close together on a chip. Examples of ORC violations may include, e.g., insufficient spacing between features, sharp corners, or large aspect ratio features, to name a few examples.

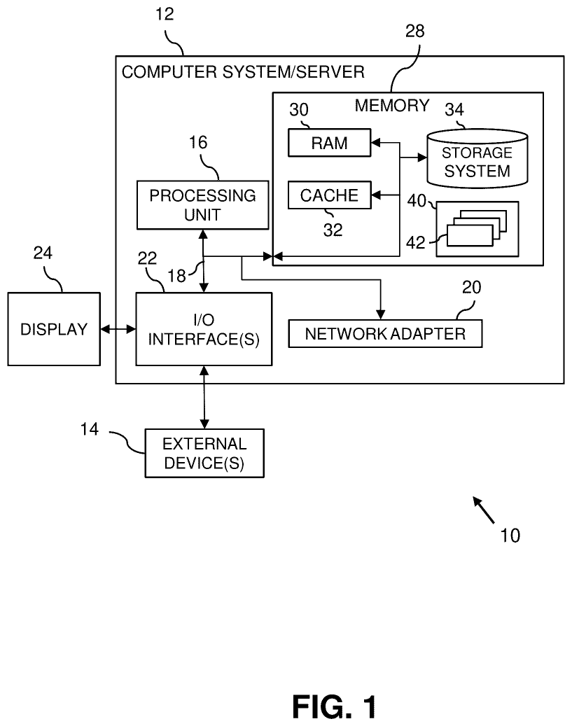

FIG. 1 depicts a cloud computing node according to an embodiment of the present disclosure. In this regard, the present disclosure may be representative of a system, a method, and/or a computer program product at any possible technical detail level of integration. The computer program product may include a computer readable storage medium (or media) having computer readable program instructions thereon for causing a processor to carry out aspects of the present disclosure. The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination. A computer readable storage medium or media, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. Computer readable program instructions for carrying out operations of the present disclosure may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages. The computer readable program instructions may execute entirely on the user's computer, partly on the user's computer, as a stand-alone software package, partly on the user's computer and partly on a remote computer or entirely on the remote computer or server.

As described in more detail with respect to FIG. 1, these computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

Referring now to FIG. 1, a schematic of an example of a cloud computing node is shown. Cloud computing node 10 is only one example of a suitable cloud computing node and is not intended to suggest any limitation as to the scope of use or functionality of embodiments of the disclosure described herein. Regardless, cloud computing node 10 is capable of being implemented and/or performing any of the functionality set forth hereinabove. Also, it is to be understood that although this disclosure includes a detailed description on cloud computing, implementation of the teachings recited herein are not limited to a cloud computing environment. Rather, embodiments of the present disclosure are capable of being implemented in conjunction with any other type of computing environment now known or later developed.

In cloud computing node 10 there is a computer system/server 12, which is operational with numerous other general purpose or special purpose computing system environments or configurations. In embodiments, the computer system/server 12 (which may be internal or external to a processing tool) may perform the functions described herein. In specific embodiments, the computer system/server 12 provides risk prediction automation and, more particularly, OPC, ORC, etc., correction weak point risk prediction automation for use in semiconductor fabrication processes.

For example, the computer system/server 12 may capture pattern information from each unique pattern ID of a chip design layout. The pattern information may include, amongst other non-limiting examples, (i) rulename information; (ii) technology type; (iii) technology node; (iv) pattern ID; (v) MinCD/AvgCD/MaxCD (in comparison to baseline or worst case violations); (vi) age of last waived status; (vii) frequency of history pass-waived and last status; (viii) raw error counts by device; and/or (ix) customer specification/information/categories of weakness, amongst other feature variables. The computer system/server 12 may generate a WDS using a machine learning scoring model that is trained on and built using risk ratings associated with selected feature variables, including historical disposition and one or more alerts associated with the historical defect handling based on the pattern information. In further embodiments, the automatic disposition of the violations may also use and train on feedback status (e.g., pass-waive or fail as provided by a user). The computer system/server 12 will provide pass-waivers of the violations and/or provide a recommendation to correct the violation, e.g., if the score is above a pre-determined threshold, the violation may be pass-waived.

As should be understood by those of skill in the art, the machine learning scoring model is a statistical model built using machine learning algorithms that assigns a numerical score to data points based on patterns learned from a training dataset, essentially predicting the likelihood of a specific outcome or ranking based on the input data. The machine learning algorithms may be based on logistic regression, decision trees, random forests, gradient boosting machines, or neural networks. And as should be understood by those of ordinary skill in the art, the machine learning scoring model takes new data as input, analyzes it using the trained model, and outputs a numerical score representing the predicted outcome. The machine learning scoring model may learn from the historical data.

Computer system/server 12 may be described in the general context of computer system executable instructions, such as program modules, being executed by a computer system. Generally, program modules may include routines, programs, objects, components, logic, data structures, and so on that perform particular tasks or implement particular abstract data types. Computer system/server 12 may be practiced in distributed cloud computing environments where tasks are performed by remote processing devices that are linked through a communications network. In a distributed cloud computing environment, program modules may be located in both local and remote computer system storage media including memory storage devices.

As shown in FIG. 1, computer system/server 12 in cloud computing node 10 is shown in the form of a general-purpose computing device. The components of computer system/server 12 may include, but are not limited to, one or more processors or processing units 16, a system memory 28, and a bus 18 that couples various system components including system memory 28 to processor 16.

Bus 18 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnects (PCI) bus.

Computer system/server 12 typically includes a variety of computer system readable media. Such media may be any available media that is accessible by computer system/server 12, and it includes both volatile and non-volatile media, removable and non-removable media.

System memory 28 can include computer system readable media in the form of volatile memory, such as random access memory (RAM) 30 and/or cache memory 32. Computer system/server 12 may further include other removable/non-removable, volatile/non-volatile computer system storage media. By way of example only, storage system 34 can be provided for reading from and writing to a non-removable, non-volatile magnetic media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 18 by one or more data media interfaces. As will be further depicted and described below, memory 28 may include at least one program product having a set (e.g., at least one) of program modules that are configured to carry out the functions of embodiments of the disclosure.

Program/utility 40, having a set (at least one) of program modules 42, may be stored in memory 28 by way of example, and not limitation, as well as an operating system, one or more application programs, other program modules, and program data. Each of the operating system, one or more application programs, other program modules, and program data or some combination thereof, may include an implementation of a networking environment. Program modules 42 generally carry out the functions and/or methodologies of embodiments of the disclosure as described herein.

Computer system/server 12 may also communicate with one or more external devices 14 such as a keyboard, a pointing device, a display 24, etc.; one or more devices that enable a user to interact with computer system/server 12; and/or any devices (e.g., network card, modem, etc.) that enable computer system/server 12 to communicate with one or more other computing devices. Such communication can occur via Input/Output (I/O) interfaces 22. Also, computer system/server 12 can communicate with one or more networks such as a local area network (LAN), a general wide area network (WAN), and/or a public network (e.g., the Internet) via network adapter 20. As depicted, network adapter 20 communicates with the other components of computer system/server 12 via bus 18. It should be understood that although not shown, other hardware and/or software components could be used in conjunction with computer system/server 12. Examples, include, but are not limited to: microcode, device drivers, redundant processing units, external disk drive arrays, RAID systems, tape drives, and data archival storage systems, etc.

As should be understood by those of skill in the art, a cloud computing environment includes one or more cloud computing nodes 10 with which local computing devices used by cloud consumers. Nodes 10 may communicate with one another. They may be grouped (not shown) physically or virtually, in one or more networks, such as Private, Community, Public, or Hybrid clouds as described hereinabove, or a combination thereof. This allows cloud computing environment to offer infrastructure, platforms and/or software as services for which a cloud consumer does not need to maintain resources on a local computing device. The model described herein may be scalable with the cloud computing environment.

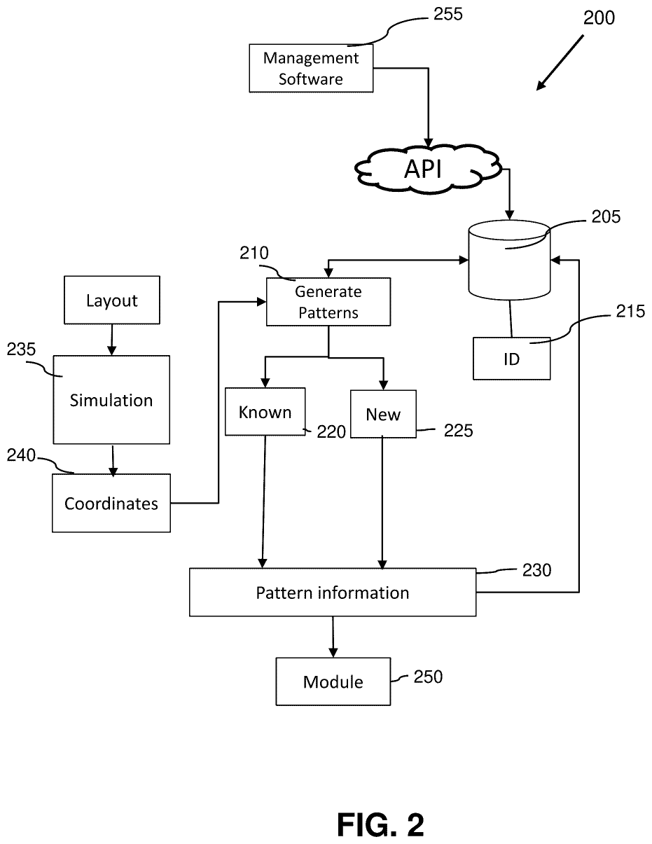

FIG. 2 shows a block diagram of an exemplary processing environment in accordance with aspects of the disclosure. For example, the block diagram 200 includes a pattern ID database 205 that may be in communication with a management and tracking software product 255 via an API. The management and tracking software product 255 may include, for example, software for tracking defects and managing projects in a semiconductor fabrication facility as is known in the art such that a further explanation is not required herein for a complete understanding of the present disclosure. It should also be understood by those of ordinary skill in the art that the management and tracking software product 255 may directly communicate with other modules/components as shown in FIG. 2.

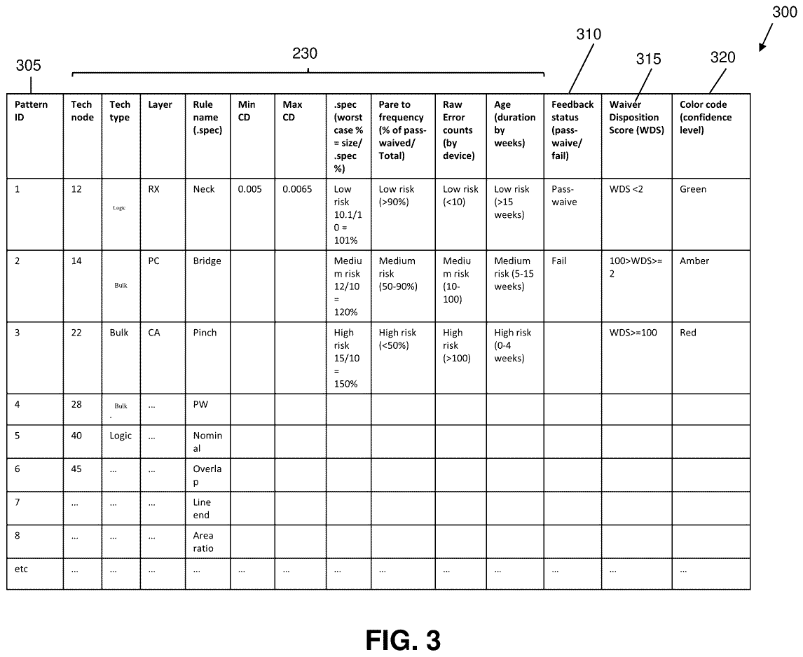

As further shown in FIG. 2, the database 205 can capture pattern information 230 for each unique pattern generated at box 210, e.g., shape of wiring lines, etc. The pattern information 230 may include different feature variables as further described with respect to FIG. 3. For example, the pattern information 230 may include: (i) rulename information; (ii) technology type; (iii) technology node; (iv) pattern ID; (v) MinCD/AvgCD/MaxCD; (vi) cumulative count (raw error count of each device); (vii) age of the last waived status; (viii) frequency of history pass-waived and last status; and/or (x) customer specifications/information/categories of weakness.

In embodiments, the pattern ID database 205 can save the historical pattern information, in addition to any new pattern information as representatively shown at boxes 220 and 225. In this way, the pattern ID database 205 will be a comprehensive database of patterns (feature variables), ratings of any violations associated with the patterns (e.g., low rank violation, etc.), a generated WDS and resultant actions (e.g., pass-waiver of violations, fails, etc.) associated with each of the design patterns as further described with respect to FIG. 3. The pattern ID database 205 may also provide a unique pattern ID to each of the different pattern information, at box 215.

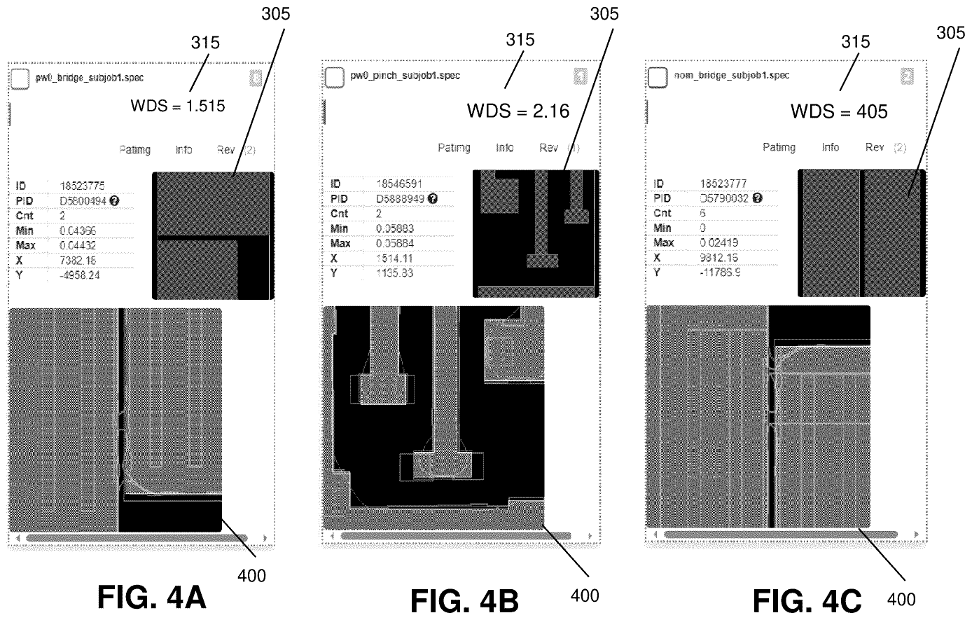

The block diagram 200 also includes a lithography simulation module 235. In embodiments, the lithography simulation module 235 utilizes layout information (as provided by the designer, technician, engineer, etc.) to generate a simulation of the design layout. The simulation of the design layout may include design violations as shown in FIGS. 4A-4C. In embodiments, the simulations may be ORC, OPC, etc. violations. The coordinates of interest of the simulation (e.g., violations of the design layout) may also be generated at box 240. In embodiments, the coordinates of any violations can be determined by conventional Electronic Design Automation (EDA) software tools known to those of skill in the art.

The coordinates of interest, the design patterns and any violations may be saved in the pattern ID database 205, with the unique pattern ID noted at reference numeral 215. The pattern ID database 205 may also save any pass-waivers, WDS, ratings of past violations and/or other actions taken with respect to the violations. For example, the additional information may be historical disposition of one or more alerts associated with historical defect handling of the different violations. In this way, the pattern ID database 205 may include both historical waiver information and can be updated (e.g., trained) with new waiver information obtained from any design layouts of new design layout simulations.

The block diagram 200 also shows an optical proximity correction weak point risk prediction automation module 250. The optical proximity correction weak point risk prediction automation module 250 uses the information in the pattern ID database 205, as discussed above, to generate the WDS and pass-waive assessments. For example, in embodiments, the optical proximity correction weak point risk prediction automation module 250 may use a machine learning scoring model built from the information of historical waiver information obtained from the pattern IDS database 250. More specifically, the information used by optical proximity correction weak point risk prediction automation module 250 to determine the WDS, pass-waive violations, etc., may include, for example, the historical feature variables and historical defect handling of different violations as it relates to a particular pattern ID (which can also be used as training data to refine waiver violations for new design layouts). In embodiments, for example, when it is determined that the violation of a new design layout is below a certain threshold, e.g., confidence level, the systems and processes described herein can waive the violations and continue with the fabrication processes.

FIG. 3 shows historical information used to determine a WDS in accordance with aspect of the present disclosure. In embodiments, the WDS may be generated from the optical proximity correction weak point risk prediction automation module 250 as shown in FIG. 2 using the historical information (e.g., feature variables) shown in the table 300 of FIG. 3. For example, the optical proximity correction weak point risk prediction automation module 250 may generate a WDS using a machine learning scoring model that is built from the feature variables 230 and historical waiver information 310 as shown in table 300 of FIG. 3. Any newly generated pattern information from new design layouts may also be entered into the system for additional training purposes. The information includes, for example, historical disposition of one or more alerts associated with the historical defect handling. Preferably, the machine learning model is updated continuously as the system handles defect waiver/rejection, thereby increasing the predictive benefit of the WDS scoring.

As shown in FIG. 3, the information used in the machine learning scoring model may include a pattern ID 300, in addition to the different pattern information e.g., feature variables) as shown at reference number 230. As disclosed already herein, it should be understood that the different pattern information may be used as training data for the machine learning of the optical proximity correction weak point risk prediction automation module 250. This data may also be used to provide the different rankings, scores and indication of violations as described herein.

In embodiments, the pattern information may include any number of different feature variables such as, for example, (i) rulename information; (ii) technology type; (iii) tech node; (iv) layer in which the pattern is provided; (v) MinCD/MaxCD (of the violation in comparison to baseline or worst case violations); (vi) customer specification (.spec); (vii) frequency; (viii) raw error counts; and (ix) age of waived status. It should be appreciated by those of skill in the art that other variables may also be provided such as average CD, etc. The rating information provided for the feature variables (v)-(ix) may be used to generate the WDS and waiver error information.

The tech node may be different technology nodes such as 12 nm, 14 nm, etc. as is known in the art. The tech type may be FDSOI, logic devices, etc. as is known in the art. The rulename may be, for example, neck, bridge, pinch, overlap, nominal etc. as is known in the art. As further shown in table 300, the specification variable, frequency variable, raw error count variable and age variable may be ranked as a high risk violation, a medium risk violation or a low risk violation. These rankings may be generated by the optical proximity correction weak point risk prediction automation module 250. For example, the risk ranking of the specification variable may be based on whether worst case %=size/specification %.

The frequency variable may be rated based on whether pass-waived/total is less than a predetermined threshold. In a non-limiting example, greater than 90% is a low risk violation, between 50%-90% is a medium risk violation and less than 50% is a high risk violation. The raw error variable may be rated based on the raw error counts of the device. In a non-limiting example, less than 10% is a low risk violation, between 10%-100% is a medium risk violation and greater than 100% is a high risk violation. In addition, the age duration (in weeks) variable may be rated based on whether pass-waived/total is less than a predetermined threshold based on weeks. In a non-limiting example, greater than 90% is a low risk violation, between 50%-90% is a medium risk violation and less than 50% is a high risk violation. It should be understood that the above noted percentages are provided for illustrative purposes and that other values are also contemplated herein, depending on the feature variables and historical information, as examples.

Based on the ratings, a feedback status at column 320 may be generated by the optical proximity correction weak point risk prediction automation module 250. The feedback status 320 may indicate which pattern IDs have a pass-waive status or a fail status. For example, a low risk violation of all the variables may be indicative of a pass-waive status, whereas a medium risk violation of all the variable may be indicative of a fail status. In embodiments, though, different variations may also be provided depending on past history and how important such violations may be in the design layout. For example, a combination of several low risk violations and a single medium risk violation may still be indicative of a pass-waive status (as described in FIG. 4), where the single medium risk violation has been found to be unimportant in the design layout, e.g., where such violation does not risk the functionality of the chip design.

FIG. 3 further shows score 315, e.g., WDS, generated by the optical proximity correction weak point risk prediction automation module 250. The score 315 may be a predictor as to how the combination of different variables (as provided with different rankings) will affect the functionality of the design layout of the chip. For example, a WDS of less than 2 may be generated when all of the feature variables for a particular pattern ID has a low violation ranking. Similarly, a medium WDS may be generated when the feature variables all have medium ranked violations (e.g., 100>WDS>=2). Similarly, a high WDS may generate when the feature variables all have high ranked violations (e.g., WDS>=100).

The optical proximity correction weak point risk prediction automation module 250 may provide the WDS to a user in many different manners including a color coding as shown in column 320. The color coding 320 may be communicated to the user via a chatbot, for example, or other graphical user interface. The color coding may be representative of a confidence level, e.g., (i) green for a low risk of issues occurring based on the ranking and core of the different variables, (ii) amber for a medium risk of issues occurring based on the ranking and core of the different variables, and (iii) red for high risk of issues occurring based on the ranking and core of the different variables.

FIGS. 4A-4C show illustrative examples in accordance with aspects of the disclosure. For example, each of the illustrative examples show a unique pattern 315 and WDS 305 for the unique pattern 315 based on a design layout 400. For each of these examples, the optical proximity correction weak point risk prediction automation module 250 may generate the WDS 305 from the feature variables as outlined, for example, in the table 300 of FIG. 3. The WDS 305 can color coded which represents a confidence level that the violation, if implemented, will be high risk, medium risk or a low risk, as generated by the optical proximity correction weak point risk prediction automation module 250. This information shown in FIGS. 4A-4C can be indicative of a chatbot conversation or graphical user interview provided to the user.

It should also be recognized by those of skill in the art that the optical proximity correction weak point risk prediction automation module 250 may feedback the results (e.g., feature variables, WDS and waive information) into the machine learning for additional training and refinement of the scoring system and pass-waive or fail status. In this way, the proximity correction weak point risk prediction automation module 250 will not rely on a static algorithm to determine whether a violation can be a pass-waive status or a fail status and, instead, will utilize a machine learning model that is updated continuously as the system handles defect waiver/rejection. This feedback process will increase the predictive benefit of the WDS.

For the unique pattern 315 of FIG. 4A, the WDS of 1.515 is within an acceptable range and will be provided with a pass-waive designation, e.g., green color code. The WDS=1.515 is based on a specification variable of 101% (low violation risk), a frequency of 100% (high violation risk), a low violation risk related to raw error count, a duration in weeks of greater than 15 weeks which is indicative of a low violation risk (as it has been occurring for a comparatively long time period) and a full status of pass-waive.

On the other hand, for the unique pattern 315 of FIG. 4B, the WDS of 2.16 is a medium risk score and will be provided with a pass-waive designation, e.g., amber color code. The WDS=2.16 and pass-waive designation is based on a specification variable of 120% (medium violation risk), a frequency of 120% (medium violation risk), a medium violation risk related to raw error count, a duration in weeks of 15 weeks which is indicative of a medium violation risk (as it has been occurring for a comparatively longer time period) and a full status of pass-waive.

For the unique pattern 315 of FIG. 4C, the WDS of 405 is a high risk score and will be provided with a fail designation, e.g., red color code. The WDS=405 and fail designation is based on a specification variable of 150% (high violation risk), a frequency of 150% (low violation risk), a high violation risk related to raw error count, a duration in weeks of 4 weeks which is indicative of a high violation risk (as it has been occurring for a comparatively short time period) and a full status of fail.

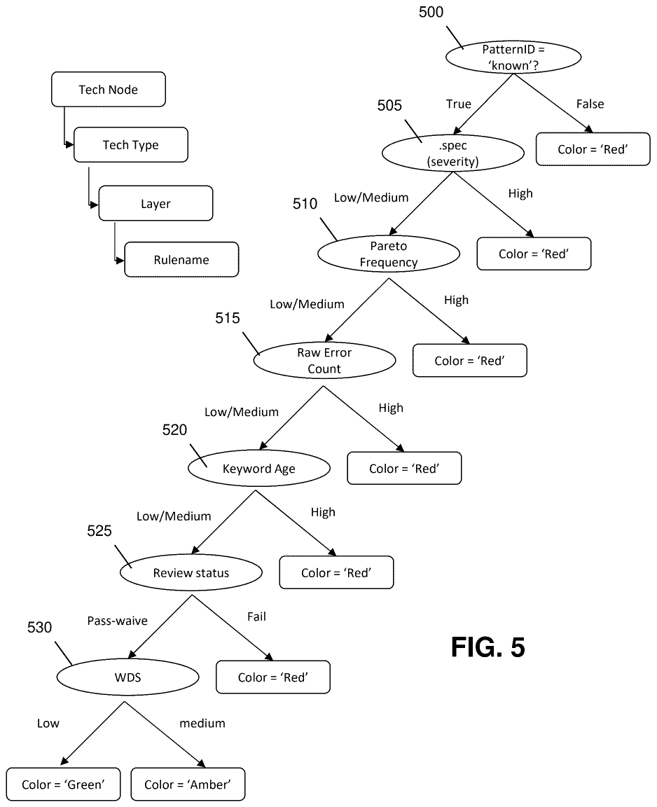

FIG. 5 shows a flowchart of an exemplary method in accordance with aspects of the present disclosure. In embodiments, the exemplary flow chart shows the prediction of a target variable using predictors and applying conditions to make decision certain decisions, e.g., waive a violation, fail status and generating a WDS.

Steps of the method may be carried out in the environment of FIGS. 1 and 2. The flowchart also illustrates the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Referring to FIG. 5, the red color coded designation refers to a new, high fail rate, and rejection. The amber color coded designation refers to waiver of the violation using engineering judgement. The green color coded designation refers to automatically waiving the violation with a high confidence. In the example of FIG. 5 the following feature variables were not taken into consideration: tech node, tech type, layer and rule name. On the other hand, the following features variables were taken into consideration: pattern ID, specification variable, frequency, raw error count, keyword age, review status and WDS. It should be understood by those of ordinary skill in the art that other feature variables may or may not be considered depending on the available information.

At step 500, if the pattern ID is now known, a red color designation would be generated. If the pattern ID is known, the processes flow to the next feature variable, e.g., specification variable.

At step 505, if the specification variable has a high violation risk, a red color designation would be generated and the processes would indicate a fail (e.g., no pass-waiver). If the specification variable has a medium or low violation risk, the processes flow to the next feature variable, e.g., frequency.

At step 510, if the frequency has a high violation risk, a red color designation would be generated and the processes would indicate a fail (e.g., no pass-waiver). If the frequency has a medium or low violation risk, the processes flow to the next feature variable, e.g., raw error count.

At step 515, if the raw error count has a high violation risk, a red color designation would be generated and the processes would indicate a fail (e.g., no pass-waiver). If the raw error count has a medium or low violation risk, the processes flow to the next feature variable, e.g., keyword age.

At step 520, if the keyword age has a high violation risk, a red color designation would be generated and the processes would indicate a fail (e.g., no pass-waiver). If the keyword age has a medium or low violation risk, the processes flow to the next feature variable, e.g., review status.

At step 525, if the review status has a high violation risk, a red color designation would be generated and the processes would indicate a fail (e.g., no pass-waiver). If the review status has a medium or low violation risk, the processes flow to the next feature variable, e.g., WDS.

At step 530, the WDS would generate a medium to low risk violation, in which case the optical proximity correction weak point risk prediction automation module 250 would generate either an amber or green color coded designation, based on a generated score.

As should now be understood, advantageously, the systems and processes described herein provide on time and reliable automatic disposition layout violations, e.g., non-conforming optical proximity correction (OPC) violations or optical rule check (ORC) violations, taking into consideration increased fabrication transfer projects and a higher number of OPC or ORC waivers needed for new keywords and/or recipes in the semiconductor fabrication process. (As should be understood by those of skill in the art, a fabrication transfer project is the process of moving a product's production and assets from one location to another.) The systems and processes also provide improved productivity by automatic disposition, in addition to being useful for retrieving historical data for fast classification, comparison, and disposition decisions. For example, by using past disposition decisions and generating a WDS, the systems and processes can determine which violations can be pass-waived by determining that such violations would not significantly affect customer specification, semiconductor device functionality or downstream processes, etc., compared to common practices which stop production when any such violations are found. Moreover, the automation processes described herein will manpower operation time for OPC technicians.

The systems and processes described herein can be utilized in the manufacture of system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method, comprising:
obtaining, by the computing device, feature variables of a design pattern associated with a design layout;
determining, by the computing device, a risk rating value of selected feature variables of the feature variables for the design pattern; and
generating, by the computing device, a waiverable disposition score using a machine learning model based on a combination of the risk rating value of the selected feature variables of the design pattern of the design layout.

2. The method of claim 1, wherein the feature variables comprises at least one of MinCD/MaxCD, customer specification, frequency of violation occurrence; raw error counts or age of waived status.

3. The method of claim 2, wherein the generating of the waiverable disposition score comprises using historical information from design patterns of different design layouts.

4. The method of claim 2, wherein the generating of the waiverable disposition score comprises using a feedback status from a user.

5. The method of claim 1, wherein the risk rating value is a calculated percentage obtained for at least one of a customer specification, a frequency of violation occurrence; raw error counts or age of waived status.

6. The method of claim 5, wherein the risk rating value comprises a low risk, a medium risk and a high risk.

7. The method of claim 1, further comprising generating a graphical user interface with the waiverable disposition score, a pass-waive status and a fail status.

8. The method of claim 1, further comprising generating a confidence level indicating that implementation of the pass-waive status or a fail status is a high risk, medium risk or a low risk.

9. The method of claim 1, wherein the machine learning model comprising a machine learning scoring model which is trained using historical information of previous design layouts.

10. A computer program product comprising one or more computer readable storage media having program instructions collectively stored on the one or more computer readable storage media, the program instructions executable to:
obtain feature variables from one or more simulated design layouts;
generate violation rules of design patterns of the one or more simulated design layouts;
save the feature variables and the violation ratings in a database; and
generate a waiverable disposition score using a machine learning model for one or more patterns of a new design layout based on the saved feature variables and the violation ratings.

11. The computer program product of claim 10, further comprising provided a confidence level that the new design layout has waiverable violations.

12. The computer program product of claim 11, wherein the confidence level comprises a high confidence level, a medium confidence level or a low confidence level.

13. The computer program product of claim 11, wherein the confidence level is based on the waiverable disposition score.

14. The computer program product of claim 10, wherein the feature variables which include the violation ratings used to generate the waiverable disposition score comprise at least one of a customer specification, a frequency of violation occurrence; raw error counts or age of waived status.

15. The computer program product of claim 10, further comprising obtaining historical data from multiple simulated design layouts, their coordinates and feature variables and using the historical data to train the machine learning model.

16. The computer program product of claim 10, wherein the waiverable disposition score is calculated from the multiple simulated design layouts, their coordinates and feature variables, in addition to a feedback status.

17. A system comprising:
a processor, a computer readable memory, one or more computer readable storage media, and program instructions collectively stored on the one or more computer readable storage media, the program instructions executable to:
determine whether multiple feature variables of a design parameter comprise a high risk rating of a design violation, a medium risk rating of the design violation and a low risk rating of the design violation;
generate a reject status should any of the feature variables comprise the high risk rating of a design violation; and
generate a pass-waive status should selected the features variable comprise the medium risk rating of the design violation and the low risk rating of the design violation.

18. The system of claim 17, further comprising using a machine learning model to generate the reject status and the pass-waive status.

19. The system of claim 18, wherein the machine learning model further comprising generating a medium confidence level and a high confidence level should the selected feature variables comprise the medium risk rating and the low risk rating, respectively.
